(19) United States
(12) Patent Application Publication
(10) Pub. No.: US 2007/0077357 A1
(43) Pub. Date: Apr. 5, 2007

(54) Source for inorganic layer and method for controlling heating source thereof

(76) Inventors: Min Jae Jeong, Yongin (KR); Do Geun Kim, Yongin (KR); Young Mook Choi, Yongin (KR)

Correspondence Address: CHRISTIE, PARKER & HALE, LLP, PO BOX 7068, PASADENA, CA, 91109-7068, US

(21) Appl. No.: 11/514,318

(22) Filed: Aug. 30, 2006

(30) Foreign Application Priority Data
Aug. 31, 2005 (KR) 10-2005-80996

(51) Int. Cl. C23C 16/00

(52) U.S. Cl. 427/248.1; 118/726

(57) ABSTRACT

A deposition source for an inorganic layer and a method for controlling a heating source thereof capable of improving a deposition efficiency, preventing condensation of a nozzle, and/or precisely controlling the temperature by minimizing the time that is needed to reach a stabilization of a deposition rate. The deposition source includes: a heating unit including a heating source for applying heat to a crucible; a housing for isolating the heat emitted from the heating unit; an outer wall for anchoring the crucible; and a nozzle unit for spraying the deposition materials evaporated from the crucible. The heating unit includes a first unit and a second unit. The crucible is positioned between the first unit and the second unit, and the heating unit includes a first power source for supplying electric power to the first unit and a second power source for supplying electric power to the second unit.

### CROSS-REFERENCE TO RELATED APPLICATION

This application claims priority to and the benefit of Korean Patent Application No. 10-2005-0080996, filed on Aug. 31, 2005, in the Korean Intellectual Property Office, the entire content of which is incorporated herein by reference.

### BACKGROUND

1. Field of the Invention

The present invention relates to a deposition source for an inorganic layer and a method for controlling a heating source thereof, and more specifically to a deposition source for an inorganic layer capable of improving a deposition efficiency, preventing a condensation of a nozzle, and/or precisely controlling a temperature by minimizing the time that is needed to reach a stabilization of a deposition rate; and a method for controlling a heating source thereof.

2. Discussion of Related Art

Generally, a deposition source can be used for thin film deposition of various electronic parts, especially for forming a thin film of electronic devices and/or display devices such as a semiconductor, an LCD, an organic electroluminescence display, etc.

The organic electroluminescence display is an electroluminescence display that injects an electron and a hole into an emitting layer from an electron injecting electrode (cathode) and a hole injecting electrode (anode), respectively, to emit light when an exciton, resulting from a coupling of the injected electron and the injected hole, falls from the excited state to the ground state.

Here, to make the hole and the electron more easily transported into the emitting layer so as to improve a light-emitting efficiency of the organic electroluminescence display, an electron transfer layer (ETL) may be arranged between the cathode and the emitting layer (organic light-emitting layer), and a hole transport layer may be arranged between the anode and the emitting layer.

Also, a hole injection layer (HIL) may be arranged between the anode and the hole transport layer, and an electron injection layer (EIL) may be arranged between the cathode and the electron transfer layer.

Generally, there are several ways to form a thin film on a substrate, including physical vapor depositions (such as a vacuum evaporation method, an ion-plating method, and a sputtering method), chemical vapor depositions by a gas reaction, etc.

Among the methods described above, the vacuum evaporation method has been mainly used for forming a thin film of an organic electroluminescence device, etc. (such as a metal film of the organic electroluminescence device, etc).

In the vacuum evaporation method, a deposition source of an indirect heating system (or an induced heating system) has been used as the deposition source. The deposition source of the indirect heating system is used to heat deposition materials received into a crucible to a predetermined temperature. The deposition source includes a heater for heating the crucible, and a nozzle unit for spraying the deposition materials emitted from the heated crucible onto a substrate.

However, the heater of the above described deposition source uses a metallic linear heating source made from a relatively expansive material such as Ta, Mo and/or W, and the heating efficiency of the metallic liner heating source is low due to its linear-type structure.

Also, an effective isolation of the heat emitted from the heater (or heating unit) for heating the crucible is required, or this heat may be transferred to other regions of the deposition source.

In addition, in order to heat the crucible so that a required deposition rate can be reached, an electric power of an electric power source is applied into the heating unit to establish an elevated temperature level of an established reference deposition rate. This electric power is kept until the agitation of the deposition rate is stabilized, and then the actual deposition is carried out during a time range of the stable deposition rate. However, in this deposition method, a large amount of time is used to stabilize the deposition rate, and this time is wasted because the deposition materials are not deposited on the substrate during this time.

Also, due to irregular heat transfer to the crucible from the heating unit, the evaporated deposition materials may condense on the nozzle unit while they flow toward the substrate, and therefore the deposition efficiency may be further deteriorated and yield of the products may be reduced.

### SUMMARY OF THE INVENTION

An aspect of the present invention provides a deposition source for an inorganic layer capable of improving a heating efficiency using a plate-type resistive heating source, improving a cooling efficiency using a mechanism for blocking heat, improving a deposition efficiency, and/or precisely controlling the temperature by independently controlling heating of its upper and lower portions to minimize the time that is needed to reach a stabilization of a deposition rate; and a method for controlling a heating source thereof.

An embodiment of the present invention provides a deposition source for a metal or inorganic layer having: a crucible arranged in a deposition chamber and for evaporating deposition materials included in the crucible; a heating unit including a heating source for applying heat to the crucible; a housing for isolating the heat emitted from the heating unit; an outer wall for anchoring the crucible; and a nozzle unit for spraying the deposition materials evaporated from the crucible, wherein the heating unit comprises a first unit and a second unit, wherein the crucible is positioned between the first unit and the second unit, and wherein the heating unit comprises a first power source for supplying electric power to the first unit and a second power source for supplying electric power to the second unit.

Here, the heating unit may include a plate-type resistive heating source, and the plate-type resistive heating source may provide a heating temperature ranging from about 400° C. to 900° C.

Another embodiment of the present invention provides a method for controlling a heating source of a deposition source for a metal or inorganic layer, the method including: controlling a temperature by respectively heating an upper heating unit and a lower heating unit adapted to supply heat to a crucible containing deposition materials; and controlling a deposition rate by fixing an electric power supplied to one of the upper heating unit or the lower heating unit and by controlling an electric power supplied to another one of the upper heating unit or the lower heating unit after reaching an elevated temperature level in the controlling of the temperature.

### BRIEF DESCRIPTION OF THE DRAWINGS

FIG. 1 is an exploded cross-sectional view showing a deposition source for an inorganic layer according to an embodiment of the present invention.

FIG. 2 is a schematic view showing a heating unit of FIG. 1.

FIG. 3 is a schematic view showing certain structures of FIG. 1.

FIG. 4 is a graph view showing an effectiveness of controlling a heating source according to an embodiment of the present invention.

### DETAILED DESCRIPTION

In the following detailed description, certain exemplary embodiments of the present invention are shown and described, by way of illustration. As those skilled in the art would recognize, the described exemplary embodiments may be modified in various ways, all without departing from the spirit or scope of the present invention. Accordingly, the drawings and description are to be regarded as illustrative in nature, rather than restrictive.

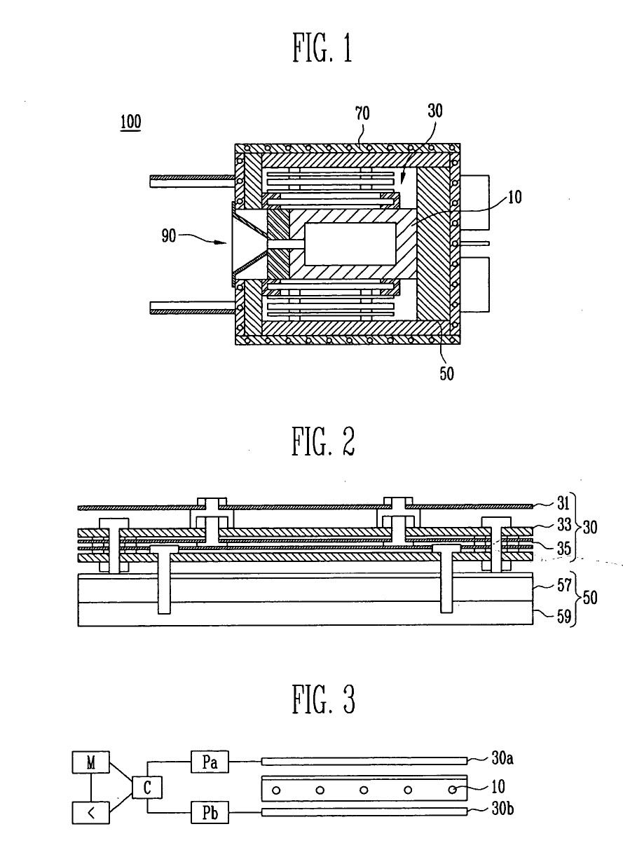

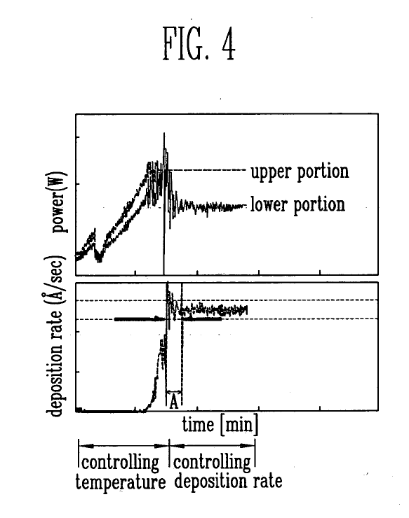

FIG. 1 is an exploded cross-sectional view showing a deposition source 100 for an inorganic layer according to an embodiment of the present invention; FIG. 2 is a schematic view showing a heating unit 30 of FIG. 1; and FIG. 3 is a schematic view showing certain structures of FIG. 1.

The deposition source 100 includes a crucible 10 arranged in a deposition chamber (not shown) and for evaporating materials included in the crucible 10; a heating unit 30 including a heating source (not shown herein) for applying heat to the crucible 10; a housing 50 for isolating the heat emitted from the heating unit 30; an outer wall 70 for anchoring the crucible 10; and a nozzle unit 90 for spraying materials evaporated from the crucible 10. In FIGS. 1, 2, and 3, the heating unit 30 includes an upper heating unit 30a and a lower heating unit 30b, and the crucible 10 is placed between the upper heating unit 30a and the lower heating unit 30b. The heating unit 30 further includes a first power source Pa for supplying electric power to the upper heating unit 30a, and a second power source Pb for supplying electric power to the lower heating unit 30b.

The crucible 10 includes deposition materials, for example metals and/or the inorganic materials such as LiF, Mg, Ag, and/or Al, and the heating units 30 are arranged around the crucible 10 to heat the crucible 10.

The crucible 10 and the heating unit 30 are installed in the housing 50, and the housing 50 is arranged to isolate a high heat emitted from the heating unit 30.

The crucible 10, the heating unit 30, and the housing 50 are anchored in the inside of the outer wall 70 to form the deposition source 100.

In addition, a nozzle unit 90 is arranged through the aforementioned housing 50 in one side of the outer wall 70 to spray the deposition materials evaporated from the crucible 10.

The upper and lower heating sources 30a and 30b are installed into an upper portion and a lower portion of the crucible 10, respectively. The heating unit 30 includes a plate-type heater 31. The plate-type heater 31 is a resistive heating source, and can be made from a material selected from carbon composites, SiC, and/or graphite. If the heater 31 is made from the material selected from carbon composites, SiC and/or graphite, the material cost is lower than that of the conventional metallic linear type heater made from a material selected from Ta, Mo and/or W. In addition, the heater 31 has an improved heating ability since it has the plate shape.

Also, the plate-type heater 31 has a larger planar area than that of the crucible 10 for effective heat transfer to the crucible 10. In order to deposit metals and/or the inorganic materials, the heater 31, a plate-type resistive heating source, provides a heating temperature ranging from 400° C. to 900° C.

Supports 33 and reflectors 35 are arranged toward an outer side of the heater 31, and, more particularly, are arranged toward the side of the outer wall 70 from the heater 31. The supports 33 are arranged in pairs to support the reflectors 35 between a pair of the supports 33, and also to support the heater 31 toward a direction in which the crucible 10 is arranged.

The reflectors 35 are arranged to isolate the heat emitted from the heater 31 to a direction of the outer wall 70. In FIGS. 1, 2, and 3, there are at least two reflectors 35, and, more particularly, there are at least four reflectors 35 in which at least two of the reflectors 35 are for the upper heating unit 30a and at least two of the reflectors 35 are for the lower heating unit 30b in order to isolate release of the heat for heating the metals and/or the inorganic materials because high temperature is required for heating the metals and/or the inorganic materials.

A heat insulating part 57 is arranged at the outside of the support 33 supporting at least 2 of the reflectors 35. The heat insulating part 57 is made of graphite felt, and covers (or is inserted on) an entire inner space of the deposition source 100 in which the crucible 10 and the heating unit 30 are arranged.

A cooling jacket 59 is mounted at an outer side of the heat insulating part 57, and the cooking jacket 59 includes a cooling path through which cooling water can be circulated.

Also, the cooling jacket 59 covers (or is inserted on) the entire inner space in which the crucible 10 and the heating unit 30 are arranged at the outer side of the heat insulating part 57.

In FIG. 3, the heating unit 30 is shown to include the upper heating unit 30a and the lower heating unit 30b positioned at an upper portion and a lower portion of the crucible 10, respectively. The upper heating unit 30a and the lower heating unit 30b receive electric power from a first power source Pa and a second power source Pb, respectively. The first power source Pa and the second power source Pb are connected to and controlled by a controller C.

In one embodiment of the present invention, the first power source Pa and the second power source Pb are independently controlled. That is, the first power source Pa and the second power source Pb are arranged so that powers supplied from the first power source Pa and the second power source Pb can be independently controlled by the controller C, respectively.

Also, the controller C further includes (or is coupled to) a measurer M for measuring a deposition rate of the metals and/or the inorganic materials emitted from the crucible 10. For an actual measurement of the deposition rate, the measurer M for measuring the deposition rate is, in one embodiment, arranged along a direction of a substrate (not shown) in the deposition source 100, and arranged at a front surface of the nozzle unit 90 in the deposition source 100. That is, the measure M is arranged in a deposition apparatus.

In addition, the controller C further includes (or is coupled to) a comparer<for comparing the deposition rate of the metals and/or the inorganic materials, obtained using the measurer M for measuring the deposition rate, to an established reference deposition rate.

Accordingly, the electric powers supplied from the first power source Pa and the second power source Pb, controlled by the controller C, may be controlled by comparing the actual deposition rate, obtained using the measurer M for measuring the deposition rate, to the established reference deposition rate, and therefore the heating of the upper heating unit 30a arranged at the upper portion of the crucible 10, and the lower heating unit 30b arranged at the lower portion of the crucible 10, may be controlled, respectively.

Hereinafter, a method for controlling a heating source of a deposition source for an inorganic layer according to an embodiment of the present invention will be described in more detail.

FIG. 4 is a graph view showing an effectiveness of controlling a heating source according to an embodiment of the present invention.

The method for controlling the heating source includes: a step of controlling a temperature by respectively heating the upper heating unit 30a and the lower heating unit 30b for supplying heat to the crucible 10 including the metals and/or the inorganic materials; and a step of controlling a deposition rate by fixing an electric power supplied to one of the upper heating unit 30a or the lower heating unit 30b, and by controlling an electric power supplied to the other one of the upper heating unit 30a or the lower heating unit 30b after reaching an elevated temperature level in the step of controlling the temperature.

The temperature of the crucible 10 including the metals and/or the inorganic is elevated above the evaporating temperature of the metals and/or the inorganic materials for their deposition. Here, the evaporating temperature of the metals and/or the inorganic materials is defined by a vapor pressure curve of the relevant material at a vacuum level in a deposition chamber (not shown).

As shown in FIG. 4, if the temperatures of the upper heating unit 30a and the lower heating unit 30b are elevated at the same time, and, more particularly, if the electric powers applied to the upper heating unit 30a and the lower heating unit 30b are gradually increased at the same time, then the metals and/or the inorganic materials are evaporated after applying the electric powers for at least a predetermined time period, that is, after a sufficient amount of heat has transferred to the crucible 10.

In one embodiment of the present invention, the method for controlling the heating source also includes: a step of measuring a deposition rate using the measurer M for measuring the deposition rate of the metals and/or inorganic materials evaporated through the step of controlling the temperature; and a step of comparing the deposition rate of the metals and/or inorganic materials measured in the step of measuring the deposition rate to an established reference deposition rate input into the controller C after the step of controlling the temperature.

The elevated temperature level of the upper heating unit 30a and the lower heating unit 30b in the step of controlling the temperature is converted into the step of controlling the deposition rate at a time when the measured deposition rate reaches 10 to 70% of the reference deposition rate; that is, the step of controlling the deposition rate is made after a control-converting step so that the electric power supplied to one of the upper heating unit 30a or the lower heating unit 30b can be fixed, and the electric power applied to the other one of the upper heating unit 30a or the lower heating unit 30b can be controlled.

Unlike a method of fixing the electric power supplied from a heating unit when the measured deposition rate reaches 100% of a reference deposition rate, the reason that the control-converting step (e.g., controlling the deposition rate by controlling a heating unit) is carried out when the measured deposition rate reaches 10 to 70% of the reference deposition rate is to reduce a stabilization time needed for stabilizing the deposition rate. That is, the desired deposition rate may be reached more rapidly by conducting the control-converting step before reaching 100% of the reference deposition rate, considering the thermal driving force of the elevated temperature and therefore an excess of the deposition rate. Accordingly, the cost of the metals and/or the inorganic materials included in the crucible 10 may be reduced.

In one embodiment, the deposition apparatus is driven in the step of controlling the deposition rate by fixing a heating temperature of the upper heating unit 30a and by controlling a heating temperature of the lower heating unit 30b, and, more specifically, by controlling the heating temperature of the lower heating unit 30b using the deposition rate.

The reason that the heating temperature of the lower heating unit 30b is controlled by the deposition rate is that the metals and/or the inorganic materials received into the crucible 10 may be present as precipitants in a lower portion of the crucible 10, and so heat applied to the lower heating unit 30b should be directly controlled. Therefore, by controlling the heating temperature of the lower heating unit 30b using the deposition rate, an embodiment of the present invention can achieve a more precise control of the deposition rate. Also, the power is fixed on the upper heating unit 30a and so the heat transferred to the evaporated metals and/or the inorganic materials prevents the condensation of the metals and/or the inorganic materials on the nozzle 90 when the evaporated materials are evaporated to the substrate.

Here, the heating of the upper heating unit 30a may be carried out by a control, that is, by properly controlling the deposition rate of the evaporated metals and/or inorganic materials, the metals and/or the inorganic materials may be prevented from being condensed due to a cold temperature while they flow toward the substrate since a sufficient amount of heat is transferred to the evaporated metals and/or inorganic materials when the deposition materials are evaporated.

As described above, a deposition source for an inorganic layer according to an embodiment of the present invention, and a method for controlling a heating source thereof, may improve the heating efficiency using a plate-type resistive heating source, and may improve the deposition efficiency and precisely control the temperature by independently controlling each heating of upper and lower portions of a crucible to minimize the time needed to reach a stabilization of the deposition rate.

While the invention has been described in connection with certain exemplary embodiments, it is to be understood by those skilled in the art that the invention is not limited to the disclosed embodiments, but, on the contrary, is intended to cover various modifications included within the spirit and scope of the appended claims and equivalents thereof.

What is claimed is:

1. A deposition source for a metal or inorganic layer comprising:
a crucible arranged in a deposition chamber and for evaporating deposition materials included in the crucible;
a heating unit including a heating source for applying heat to the crucible;
a housing for isolating the heat emitted from the heating unit;
an outer wall for anchoring the crucible; and
a nozzle unit for spraying the deposition materials evaporated from the crucible,
wherein the heating unit comprises a first unit and a second unit, wherein the crucible is positioned between the first unit and the second unit, and wherein the heating unit comprises a first power source for supplying electric power to the first unit and a second power source for supplying electric power to the second unit.

2. The deposition source for the metal or inorganic layer according to claim 1, further comprising a controller for controlling the first power source and the second power source.

3. The deposition source for the metal or inorganic layer according to claim 2, wherein the controller independently controls the first power source and the second power source, respectively.

4. The deposition source for the metal or inorganic layer according to claim 2, wherein the controller further comprises a measurer for measuring a deposition rate of the deposition materials evaporated from the crucible.

5. The deposition source for the metal or inorganic layer according to claim 4, further comprising a comparer for comparing the deposition rate of the deposition materials to an established reference deposition rate.

6. The deposition source for the metal or inorganic layer according to claim 1, wherein the heating unit comprises a plate-type resistive heating source.

7. The deposition source for the metal or inorganic layer according to claim 6, wherein the plate-type resistive heating source comprises a material selected from the group consisting of carbon composites, SiC, graphite, and combinations thereof.

8. The deposition source for the metal or inorganic layer according to claim 6, wherein the plate-type resistive heating source provides a heating temperature ranging from about 400° C. to 900° C.

9. The deposition source for the metal or inorganic layer according to claim 1, further comprising a reflector between a part of the outer wall and a part of the housing to prevent a heat transfer from the heating source to a direction of the outer wall.

10. The source for the metal or inorganic layer according to claim 1, wherein the reflector comprises at least two reflectors.

11. A method for controlling a heating source of a deposition source for a metal or inorganic layer, the method comprising:
controlling a temperature by respectively heating an upper heating unit and a lower heating unit adapted to supply heat to a crucible containing deposition materials; and
controlling a deposition rate by fixing an electric power supplied to one of the upper heating unit or the lower heating unit and by controlling an electric power supplied to another one of the upper heating unit or the lower heating unit after reaching an elevated temperature level in the controlling of the temperature.

12. The method according to claim 11, wherein after the controlling the temperature, the method further comprises:
measuring a measured deposition rate of the deposition materials evaporated through the controlling of the temperature; and
comparing the measured deposition rate to an established reference deposition rate.

13. The method according to claim 12, further comprising control-converting the controlling of the temperature into the controlling of the deposition rate when the measured deposition rate reaches from about 10 to 70% of the established reference deposition rate.

14. The method according to claim 11, wherein the controlling of the deposition rate comprises fixing a heating temperature of the upper heating unit and controlling a heating temperature of the lower heating unit.

15. The method according to claim 14, wherein the heating temperature of the lower heating unit is controlled by using the measured deposition rate.

16. A method for controlling a heating source of a deposition source for a metal or inorganic layer, the method comprising:
controlling a temperature by respectively heating a first heating unit and a second heating unit adapted to supply heat to a crucible containing deposition materials; and
controlling a deposition rate by fixing an electric power supplied to the first heating unit and by controlling an electric power supplied to the second heating unit after reaching an elevated temperature level in the controlling of the temperature.

17. The method according to claim 16, further comprising:
measuring a measured deposition rate of the deposition materials evaporated through the controlling of the temperature; and
comparing the measured deposition rate to an established reference deposition rate.

18. The method according to claim 17, wherein the controlling of the temperature is converted into the controlling of the deposition rate when the measured deposition rate reaches from about 10 to 70% of the established reference deposition rate.

19. The method according to claim 16, wherein the first heating unit is an upper heating unit and the second heating unit is a lower heating unit.

20. The method according to claim 19, wherein the heating temperature of the lower heating unit is controlled by using the measured deposition rate.
